(19) United States
(12) Patent Application Publication
(10) Pub. No.: US 2026/0118774 A1
(43) Pub. Date: Apr. 30, 2026

(54) GENERATIVE ARTIFICIAL INTELLIGENCE FOR GENERATION OF CONTROL INSTRUCTIONS FOR LITHOGRAPHY-PROCESS INSPECTION TOOL

(71) Applicant: Carl Zeiss SMT GmbH, Oberkochen (DE)

(72) Inventors: Bjoern Brauer, Magstadt (DE); Bjoern Froehlich, Jena (DE); Alexander Freytag, Erfurt (DE); Michael Niebisch, Jena (DE)

(21) Appl. No.: 19/367,192

(22) Filed: Oct. 23, 2025

(30) Foreign Application Priority Data
Oct. 25, 2024 (DE) 102024131263.7

(51) Int. Cl. G03F 7/00; G06F 16/332; G06T 7/00

(52) U.S. Cl. CPC G03F 7/7065; G03F 7/70525; G03F 7/706837; G06F 16/332; G06T 7/0004; G06T 2207/30148

(57) ABSTRACT

Various examples of the disclosure pertain to operating a lithography-process inspection tool such as an actinic microscope. According to various examples, a language model is used to generate control instructions. The language model takes into account a user query as well as tool context data that includes prior knowledge on the operation of the lithography-process inspection tool.

### CROSS-REFERENCE TO RELATED APPLICATION

This application claims priority to German Patent Application 10 2024 131 263.7, filed on Oct. 25, 2024, the entire content of which is incorporated herein by reference.

### TECHNICAL FIELD

Various examples of the disclosure generally pertain to generating control instructions for a lithography-process inspection tool using generative artificial intelligence.

### BACKGROUND

Lithography is a process used in the fabrication of semiconductor structures where a lithography mask, also known as a photomask or reticle, is used to transfer patterns onto a wafer. The lithography mask contains transparent and opaque regions that define the semiconductor structures. During exposure, light passes through or is reflected by the lithography mask and onto the wafer, creating an image of the pattern on the photoresist coating. This exposed pattern is then used as a template to create semiconductor structures, such as transistors, interconnects or memory cells, which are the building blocks of modern electronic devices.

Lithography-process inspection tools can be used to check whether the lithography process is mitigated, e.g., by a defective photomask, or whether the semiconductor structures exhibit defects.

Such lithography-process inspection tools are complex and include many components and parameter setting options. To control them, control instructions are used. Such control instructions specify, e.g., a sequence of operating steps of the lithography-process inspection tool and/or parameter settings.

The current state-of-the-art for generating control instructions, also referred to as “recipes”, for lithography-process inspection tools involves manual preparation by highly skilled and experienced personnel. The process of setting up control instructions is complex and dependent on numerous factors. As a result, the creation of a new control instruction typically requires weeks or even months of training for a qualified individual. Furthermore, even experienced professionals may struggle with creating control instructions due to the high degree of customization required for each specific customer site. The rarity of experts with such specialized knowledge and experience only exacerbates this issue, as they are often not readily available when a new control instruction needs to be generated. Moreover, when tools undergo upgrades, these experts must also undergo retraining to ensure optimal utilization of the updated equipment.

### SUMMARY

It is therefore an aspect of the present disclosure to simplify the generation of control instructions for lithography-process inspection, thereby overcoming the above-mentioned disadvantages of the prior art at least in part.

One aspect of the present disclosure relates to a method of determining control instructions for operating a lithography-process inspection tool. The method comprises obtaining a user query in free-text format, the user query being indicative of a task to be carried out by the lithography-process inspection tool on a sample. The method further comprises obtaining tool context data comprising prior knowledge on operation of the lithography-process inspection tool. Based on the user query and based on the tool context data, one or more inference-runs of at least one language model are triggered, to thereby generate the control instructions.

In some embodiments, the lithography-process inspection tool may be understood as an optical system that uses light to inspect a photolithography mask or wafer. In a photolithography process, the photolithography mask is irradiated with light (e.g., extreme ultraviolet light) to transfer the integrated circuit pattern via the photolithography mask to a substrate by use of a light-sensitive chemical process. Such a mask inspection tool may refer to an optical system that can, for example, be used for defect-detection tasks, detecting defects in a photolithography mask by capturing an aerial image of the photolithography mask. Example defects are clear defects, opaque defects, bridge defects, etc. An optical mask qualification system refers to a system that may be used for an imaging task, for example to capture an image of a portion of a photomask, in particular of potential defects detected using an inspection system. The optical mask qualification system may, e.g., emulate settings of a photolithography system, e.g., illumination and imaging parameters, to examine the effect of a potential defect on a printed wafer, to verify that photolithography masks are defect-free or whether a repair attempt has been successful. An example lithography-process inspection tool to inspect lithography masks is an actinic microscope.

A user query may be understood as request provided by a user that defines the specific task or objective to be achieved by the lithography-process inspection tool. The user query may be provided in free-text format.

Tool context data may be understood as prior knowledge or information about the lithography-process inspection tool, e.g., including its capabilities and limitations during operation, available components or modules, etc. The tool context data obtained for the method may include various types of information related to the operation of the lithography-process inspection tool. For example, working hours of the lithography-process inspection tool and/or the lithography mask, light source quality, and multiple sensor data such as light intensity measurement, interferometers for defocus, ambient pressure of gases, or others can be part of the tool context data. Alternatively or additionally, a log file from the tool can also provide valuable information that is incorporated into the tool context data. This can include historical performance data, maintenance records, or other relevant details about the tool's operation over time. For instance, if it is determined from the tool context data that the light source has degraded over years, the scan speed may need to be adjusted accordingly to ensure optimal performance. This may be specified in the control instructions.

A language model (LM) may be understood as a machine learning model that is trained on a large corpus of text data and can generate human-like responses to user queries. The architecture typically involves layers of neural networks, often using transformers. During training, the model learns to predict the next word in a sentence, refining its ability to understand context and syntax. LMs are trained on vast amounts of data and have millions or even billions of parameters (large LMs).

LMs can be trained to reproduce output of other LMs, e.g., a small language model (small LM) can be trained from output or internal calculations from a large language model (large LM), which is sometimes referred to as knowledge distillation.

The LM may be based on reinforcement learning (RL-based LM). RL-based LMs may develop reasoning capabilities without supervised data, focusing on self-evolution through a reinforcement training/learning process. Reinforcement learning is a type of machine learning where an agent interacts with an environment by observing its state, taking actions based on a policy, and receiving rewards that guide it to learn better actions over time. The goal is to find a policy that maximizes cumulative rewards by making optimal decisions in different states. The reward is the source of a training loss which decides the optimization direction. This can be, e.g., a rule-based reward system such as an accuracy reward which evaluates whether the response is correct. This can be done by providing the model with a final answer or a solution to a predefined test case.

The language of the user query may be any language supported by the LM, allowing users to interact with the system in their native language or language of choice. This flexibility is enabled by cross-attention models, which are capable of processing multi-language inputs. For example, a user may submit a user query in German, while requesting that the control instructions be generated in English. Cross-attention models can be understood as machine learning architectures that allow for attention mechanisms to be applied across multiple input sequences, e.g., multiple input languages, enabling the LM to capture relationships and dependencies between different input sequences. Thereby, for instance, tool manuals in foreign languages can be accessed.

To ensure data security and confidentiality, the LM can be hosted on a locally connected device at the tool, such as a computer or server located within the semiconductor fabrication site (FAB). This setup prevents any sensitive information, including user queries and generated control instructions, from leaving the FAB. Alternatively, the LM can also be hosted in a remote-connected server, such as a cloud server, provided that adequate security measures are taken to protect sensitive data.

In such a scenario, triggering the one or inference-runs of the at least one LM may include providing respective inference control instructions to the server, e.g., an encrypted format; and/or receiving output data from the server, e.g., in encrypted format.

As will be appreciated, techniques have been disclosed above in which a generative artificial intelligence—here, the LM—is used for generating the control instructions for the lithography-process inspection tool. A user query in free-text format can be considered, as well as the tool context data. An effect may be reduced time for creating useful control instruction. This also reduces the risk of poor or malfunctioning control instruction. Additionally, this enables less experienced personnel to create high-quality control instructions, as the method provides a structured approach to generating control instructions that is not highly dependent on human expertise to a degree of manual prior art approaches.

In an example, the sample may be a semiconductor wafer or a lithography mask.

A semiconductor wafer may be understood as a thin slice of semiconductor material, typically silicon, e.g., used as a substrate for fabricating integrated circuits. A lithography mask, on the other hand, is a template used in photolithography to transfer patterns onto a semiconductor wafer.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 5 to 7 inches long and wide, most preferably 6 inches long and wide. Alternatively, the photolithography mask may be 5 to 7 inches long and 10 to 14 inches wide, preferably 6 inches long and 12 inches wide.

Using the disclosed techniques, various tasks can be implemented. Some examples are provided below. An imaging task may be defined by the control instructions, i.e., to capture images of the wafer and/or the lithography mask. This is typically done to verify that the pattern transferred onto the wafer accurately reflects the design intent, or to detect any defects in the semiconductor structures. A defect-detection task includes to identify and optionally classify defects such as contamination, scratches, or pattern errors on the wafer or lithography mask.

Defects may be defined as localized deviations of an integrated circuit pattern from an a priori defined norm of the integrated circuit pattern formed by the semiconductor structures. The norm of the integrated circuit pattern can be defined using one or more corresponding reference objects or reference images, e.g., by a design of the photolithography mask, simulated datasets or acquired defect-free datasets, or using models. A maximum deviation from the norm, e.g., 10% of the critical dimension, can, for example, be used to distinguish between defects and nuisances or between relevant and irrelevant deviations.

A defect-detection task helps in ensuring that only wafers of sufficient quality are processed further. A micro-manipulation task refers to the precise movement of microscopic objects, such as probes or particles. In the context of lithography-process inspection, this may involve manipulating particles on the surface of the wafer or mask. A repair task involves making corrections or modifications to the wafer or lithography mask to rectify defects detected during the defect-detection task. This may include re-etching or re-depositing material onto specific areas of the wafer, and/or modifying the design pattern on the lithography mask.

In an example, the method may include obtaining tool context data that includes an operating manual of the lithography-process inspection tool.

An operating manual may be understood as a document that provides detailed information about the operation of the lithography-process inspection tool, including its capabilities and limitations. This arrangement may enable the creation of tool-specific control instructions, taking into account the specific features and constraints of the tool. Additionally, this arrangement may allow for the learning of a tool-specific control language or script language from the operating manual. An operating manual may refer to a detailed document or set of instructions that describes the operation, functionality, and maintenance of a lithography-process inspection tool. The operating manual may include information about the complexity of the tool, such as the number of components, subsystems, or software modules it comprises, which can make it challenging for users to fully understand its capabilities without significant time investment. Due to its size and detailed nature, an operating manual may require a substantial amount of time to study and learn, particularly for personnel who are not familiar with the intricacies of modern lithography-process inspection tools. The document may provide details regarding both hardware and software aspects of the tool, such as descriptions of sensors, actuators, data acquisition systems, or control algorithms, as well as user interfaces or programming environments used to interact with the tool. Furthermore, the operating manual may outline the device's capabilities, such as its resolution, sensitivity, or throughput, while also specifying its limitations, such as environmental conditions, temperature ranges, or material compatibility constraints that must be observed during operation. By understanding these aspects, users can optimize the performance of the lithography-process inspection tool and avoid potential misuse or suboptimal settings.

In an example, the method may include obtaining tool context data that includes multiple reference control instructions for at least one of the task or one or more other tasks.

Reference control instructions may be understood as pre-existing instructions that have been used for similar tasks—e.g., for that particular lithography-process inspection tool—in the past, which can serve as examples or templates for generating new control instructions.

By using such reference control instructions, specific examples are available for the LM to generate the control instructions for the particular task at hand. The results of the generative AI can be improved by providing specific examples.

In an example, the method may include obtaining tool context data that includes multiple reference control instructions for at least one of the task or one or more other tasks, and labels associated with each of the multiple reference control instructions.

Labels associated with each reference control instruction may be understood as indicators of whether the respective task is accomplished by the respective reference control instructions, providing ground truth for evaluating the effectiveness of the reference control instructions. For instance, these may be binary labels, e.g., indicating by a “1” that the respective task has been successfully accomplished by the associated reference control instruction; alternatively, a “0” may provide an indication that the respective reference control instructions do not accomplish the task. Furthermore, beyond such binary labels, regression labels would be possible; here, a number selected from a continuous range may indicate a degree to which reference control instructions accomplish a task. These labels may be defined in any appropriate metric.

This arrangement may enable the method to identify good or bad examples among the reference control instructions. The labels may serve as a quality metric for the reference control instructions, allowing the method to distinguish between successful and unsuccessful examples. This, in turn, allows the LM to refine its understanding of what constitutes an effective control instruction, leading to improved performance and reliability.

In an example, the method may include obtaining tool context data that includes at least one of: an operational status of the lithography-process inspection tool, an operational history of the lithography-process inspection tool, a fault indicator of the lithography-process inspection tool, tool meta data of the lithography-process inspection tool, and/or sensor data associated with the lithography-process inspection tool.

Operational status may be understood as current information about the mode of operation of the lithography-process inspection tool, such as whether it is idle or has been idle for a certain time, running a process or has been running a process for a certain time, or whether it has been undergoing maintenance recently.

Operational history may include past events, usage patterns, and performance metrics of the lithography-process inspection tool; it can provide insights into the behavior of the lithography-process inspection tool over time. Drifts of operational parameter values may be indicated. It may be indicative of the last used control instructions, recently investigated samples, etc.

A fault indicator may be indicative of potential issues with the functionality of the lithography-process inspection tool. A lithography-process inspection tool can experience various types of faults or errors. Optical system faults may include lens contamination or damage. Stage and motion system faults can occur due to stage calibration errors, inaccurate positioning or movement, stage collision or overrun, and motor failure or overheating. Sensing and detection faults may be caused by detector saturation or overload, incorrect detector settings such as gain or offset, sensor contamination or damage, and signal processing errors. Environmental control faults can include temperature control issues like overheating or cooling failure, humidity control problems, and airflow or gas flow issues.

Tool meta data may comprise information about the tool's configuration, calibration, and settings, which can affect its operation and output.

Sensor data associated with the lithography-process inspection tool may include readings from various sensors that monitor environmental conditions, such as temperature, humidity, or vibrations, which can impact the performance of the lithography-process inspection tool.

An effect of this arrangement is that it provides comprehensive knowledge of the operation of the lithography-process inspection tool, enabling the LM to take into account a current state of the lithography-process inspection tool when generating the control instruction.

Above techniques have been disclosed in which the control instruction is generated taking into account the tool context data. Alternatively or additionally, it is also possible to take into account information on the sample.

In an example, the method may further comprise obtaining sample context data associated with the sample. The one or more inference-runs of the at least one LM may be triggered further based on the sample context data.

Sample context data may include information about the sample's composition, structure, and properties. A sample type may be indicated. This data can provide insights into the sample's behavior and characteristics. The sample context data may include information on a type of the sample, e.g., wafer or mask, e.g., certain structure types expected for the wafer or mask, etc. The sample context data may include a layout file of the mask or semiconductor structures.

In an example, this sample context data may be used to generate sample-specific control instructions. This means that the inspection process can be tailored to the specific needs of a particular sample type. An effect of this arrangement is that certain inspection tasks regularly associated with a certain sample can be considered. For instance, if a sample has a known tendency to exhibit defects in a particular area, the method may prioritize inspecting those areas more thoroughly. This arrangement also allows for defects typical for a sample to be checked specifically.

In an example, the sample context data may include information that is based on at least one of imaging data of the sample or reference imaging data of a reference sample.

Imaging data of the sample may be understood as visual representations of the actual sample, which can provide detailed information about its topography, structure, and composition. Reference imaging data of a reference sample may be understood as visual representations of a sample that is similar in type to the actual sample and may have certain nominal properties (e.g., no defects or specific defects of a given type, etc.), which can serve as a basis for comparison.

As will be appreciated from the above, generally, in addition to textual information, images may also be used for the generation of control instructions for operating the lithography-process inspection tool. This multi-modal approach can provide additional spatial information about the current state of the mask or wafer or other relevant features. To incorporate images into the method, image encoders such as Vision Transformer (ViT) encoders can be used to encode the images (thereby yielding a feature representation of machine-learned features of the imaging data) and fuse such feature vectors with textual information via attention-modules.

The LM can be instructed to consider aspects of the images, such as “noise level”, “line-edge roughness”, “structures”, or “corner rounding”, when generating control instructions. For example, the LM can be prompted to take into account the noise level in the image and adjust the control instructions accordingly. Additionally, the LM can be instructed to compare the image with other historical images and their corresponding control instructions, thereby creating an implicit metric for similarity between images.

This approach has several advantages, including the ability to consider additional spatial information about the current state of the sample or other relevant features when generating control instructions. Furthermore, this method can provide a more comprehensive understanding of the relationship between images and control instructions, allowing for more accurate and effective operation of the lithography-process inspection tool.

In an example, the sample context data may include a free-text-description of one or more properties of the sample.

A free-text-description may be understood as a written description of the sample's characteristics, features, and attributes in a flexible and unstructured format. This allows a user to quickly and easily describe the sample without requiring specific formatting or syntax. For instance, an example free-text description of a VRAM sample may be as shown in TAB. 1.

TABLE 1
Example free-text descriptions of various sample types. These free-text
descriptions focus on geometrical and material properties of the samples.

The sample is a VRAM sample that features a monocrystalline silicon (100) substrate with N-
type and P-type wells. The surface includes rectangular shallow-trench isolation oxides,
defining active stripes. Parallel wordlines extend across the array with a uniform pitch of 50
nanometers. Orthogonal metal-1 bitlines form a grid over the cell array, intersecting the
wordlines at regular intervals. Each memory cell contains stacked cylindrical storage
capacitors above access transistors, measuring approximately 30 nanometers in height and 20
nanometers in diameter. L-shaped silicon nitride sidewall spacers are present around gate
stacks, each with a width of about 10 nanometers. Vertical tungsten contact plugs, shaped as
cylindrical vias, connect source/drain regions to the first metal layer (M1). Planarized
interlayer dielectrics made of oxide and low-k materials separate the metal levels, ensuring a
flat surface. The interconnects consist of multilevel copper strips from M1 to M4, with stacked
via arrays for signal routing. The top passivation layer is composed of silicon nitride and
polyimide, featuring rectangular openings over bond pads measuring 100 micrometers in
length and width.
The sample is a CPU sample that is based on a monocrystalline silicon substrate with shallow-
trench isolation trenches defining active regions. The STI trenches have a width of 120 nm and
a depth of 300 nm. Parallel FinFET structures are integrated, with a fin pitch of 32 nm, a fin
width of 7 nm, and a fin height of 50 nm. Tri-gate metal gate stacks are present, with a gate
length of 22 nm, a gate pitch of 52 nm, and a spacer thickness of 7 nm. Self-aligned contact
trenches have a width of 30 nm, with vertical tungsten plugs extending 90 nm in height.
Standard-cell rows are arranged in a multilevel structure, with a row height of 7.5 tracks,
corresponding to approximately 240 nm at a track pitch of 32 nm. Local interconnects (M0-
M1) consist of unidirectional lines with a width of 15 nm, a pitch of 32 nm, and a thickness of
30 nm. Stacked vias (V0-V3) have a critical diameter of 25 nm and a via enclosure of 7 nm.
Upper metal layers (M6-M10) are used for global wiring, with a line width of 400 nm and a
pitch of 800 nm. These upper metals are fabricated using dual-damascene copper in low-k
dielectric material. The clock distribution network is implemented H-tree.

An effect of this arrangement is that it simplifies the process of providing context data about the sample. By allowing users to describe the sample in their own words, the system reduces the burden on the user and eliminates the need for extensive prior image acquisition, etc.

In an example, the sample context data may include a process history of a fabrication process for obtaining the sample.

A process history may be understood as a record of the steps and conditions involved in creating or manufacturing the sample. For instance, certain lithography steps or lithography chemicals may be described. Example process steps in a lithography process are: Wafer Cleaning, Photoresist Application, Soft Bake, Exposure, Post-Exposure Bake, Development, Hard Bake, Etching, Photoresist Removal. The process history may include information about temperature, pressure, chemical composition, and other parameters that were controlled during the fabrication process.

An effect of this arrangement is that it helps to prompt the LM to generate a control instruction that is tailored to detect likely defects, e.g., resulting from certain specific process steps having significant exposure to process deviations. This arrangement enables the LM to identify correlations between specific steps or conditions in the fabrication process and particular types of defects. As a result, this arrangement enables generation of control instructions that enable more targeted inspections, as the LM can generate control instructions that are specifically designed to detect the most likely defects given the process history.

In an example, the sample context data may include an ageing status of the sample.

An ageing status may be understood as information that indicates the length of time the sample has been in use, its frequency of use, or other factors that affect its condition over time. For instance, the aging/wear status of a lithography mask may indicate the number of exposure steps executed with that lithography masks. The aging status of a lithography masks may be indicative of the total light exposure dose over the lifespan of the lithography mask. Number of cycles, and/or exposure to environmental stressors may be indicated.

This arrangement provides context for the LM to anticipate likely defects or degradation in the sample. Certain defects may only occur at specific ageing statuses, making it helpful to consider this information when inspecting the sample. The control instructions can be tailored to the ageing status of the sample.

In an example, control instructions may include script code for controlling one or more modules of the lithography-process inspection tool. The control instructions may alternatively or additionally include script code for analyzing imaging data acquired using the lithography-process inspection tool. An example script code is provided below in TAB. 2.

TABLE 2
Example script code for controlling a SEM to image a CPU sample. Illustrated in script code
for automating the operation of an SEM or a similar lithography-process inspection tool. It
begins with the setup phase in which a connection to the SEM controller is established, the
vacuum environment is pumped down, and the stage is positioned at predefined coordinates.

###SCriptcode
# ----------------------------
# 0) “API” placeholders
# ----------------------------

| | |
|---|---|
| def connect(address=None): | print(“→ Connect to SEM controller”) |
| def pump_down( ): | print(“→ Pump down / reach HighVac”) |
| def move_stage(x_mm, y_mm): | print(f“→ Move stage to X={x_mm} mm, Y={y_mm} |

mm”)

| | |
|---|---|
| def set_tilt(deg): | print(f“→ Set stage tilt = {deg}°”) |
| def set_rotation(deg): | print(f“→ Set stage rotation = {deg}°”) |
| def set_beam_energy(keV): | print(f“→ Set beam energy = {keV} keV”) |
| def set_probe_current(pA): | print(f“→ Set probe current = {pA} pA”) |
| def set_aperture(um): | print(f“→ Select aperture = {um} μm”) |
| def set_working_distance(mm): | print(f“→ Set working distance = {mm} mm”) |
| def select_detector(name): | print(f“→ Select detector = {name} (SE/BSE)”) |
| def set_magnification(x): | print(f“→ Set magnification ≈ {x}×”) |
| def set_resolution(w, h): | print(f“→ Set resolution = {w}×{h} px”) |
| def set_dwell(us): | print(f“→ Set dwell time = {us} μs/pixel”) |
| def set_frame_avg(n): | print(f“→ Set frame averaging = {n} frames”) |
| def enable_drift_corr(on=True): | print(f“→ Drift correction = {‘ON’ if on else ‘OFF’}”) |
| def auto_focus( ): | print(“→ Auto-focus”) |
| def auto_stig( ): | print(“→ Auto-stigmation”) |
| def auto_bc( ): | print(“→ Auto brightness/contrast”) |

```
def acquire_frame(label):
  ts = datetime.now( ).strftime(“%Y%m%d_%H%M%S”)
  filename = f“{label}_{ts}.tif”
  print(f“→ Acquire frame → save as {filename} (with scalebar & metadata)”)
  return filename
```

| | |
|---|---|
| def disconnect( ): | print(“→ Disconnect”) |

```
# ----------------------------
# 1) Parameters # ----------------------------
SE_PASS = {
  “label”: “CPU_SE_3keV”,
  “detector”: “SE”,
```

| | |
|---|---|
| “keV”: 3.0, | # surface/topography |
| “current_pA”: 200, | # SNR without big spot size |

```
  “aperture_um”: 30,
  “WD_mm”: 8.0,
```

| | |
|---|---|
| “mag”: 5000, | # metal lines, vias visible |

```
  “res”: (3072, 2048),
  “dwell_us”: 5.0,
  “avg”: 8,
  “drift_corr”: True,
}
BSE_PASS = {
  “enabled”: True,
  “label”: “CPU_BSE_10keV”,
  “detector”: “BSE”,
```

| | |
|---|---|
| “keV”: 10.0, | # material (Z) contrast |

“current_pA”: 500,

| | |
|---|---|
| “avg”: 8, | # reuse other scan settings |

```
}
# ----------------------------
# 2) Recipe steps
# ----------------------------
def run_cpu_recipe( ):
  print(“\n=== START: CPU imaging recipe (illustrative) ===”)
  # A) Instrument & sample setup
  connect( )
  pump_down( )
  move_stage(x_mm=0.0, y_mm=0.0)
```

| | |
|---|---|
| set_tilt(0.0) | # keep 0° for metrology; small tilt adds relief |

```
  set_rotation(0.0)
  # B) Secondary Electron (SE) pass → topography
  print(“\n--- SE pass (surface topography) ---”)
  select_detector(SE_PASS[“detector”])
  set_beam_energy(SE_PASS[“keV”])
  set_probe_current(SE_PASS[“current_pA”])
  set_aperture(SE_PASS[“aperture_um”])
  set_working_distance(SE_PASS[“WD_mm”])
  set_magnification(SE_PASS[“mag”])
  set_resolution(*SE_PASS[“res”])
  set_dwell(SE_PASS[“dwell_us”])
```

| | |
|---|---|
| set_frame_avg(1) | # quick frame for auto routines |

```
  enable_drift_corr(True)
  auto_focus( )
  auto_stig( )
  auto_bc( )
  # return to “nice” settings
  set_frame_avg(SE_PASS[“avg”])
  set_dwell(SE_PASS[“dwell_us”])
  enable_drift_corr(SE_PASS[“drift_corr”])
  se_file = acquire_frame(SE_PASS[“label”])
  # C) Wrap up
  disconnect( )
  print(“\n=== DONE ===”)
```

Then, in a configuration phase, the secondary electron detector is selected. Secondary electron mode enables to capture surface topography (e.g., while backscattering electron mode would enable to provide material contrast). Beam parameter adjustments are being made to set the electrons beam energy, current, aperture size, and working distance. Then, the scan setting such as magnification and resolution as well as image quality adjustments, e.g., dwell time for pixel charging, frame averaging, etc., are being set. Next, in a stabilization phase, auto-focus, as stigmatism correction and brightness/contrast are set. Finally, the script continues to trigger capturing of images using these optimized settings, saving them in filenames. After imaging is complete, the script disconnects from the SEM controller.

A module of the lithography-process inspection tool may be understood as a functional component that performs a specific task, such as image acquisition, manipulation, or stage movement, etc.

Script code, in this context, may refer to a set of instructions written in a programming language that can be executed by the tool's control system or another processing device. Script code may not need to be compiled by a compiler; rather, it may be read by an executable program. An example of a script code is a configuration file, e.g., in xml format.

This arrangement allows for automated control of the lithography-process inspection tool, enabling it to perform tasks without manual intervention. Images acquired using the tool may be automatically evaluated using the script code, reducing the need for labor intensive configuration of an imaging software.

In an example, generating control instructions may include one or more iterations. Each iteration may comprise generating a respective prompt for at least one LM based on a user query. The inference-run of the at least one LM may be triggered in each iteration based on the respective prompt. Different iterations may use different prompts.

An inference-run refers to the process of executing the LM with a specific input, such as a prompt, to generate an output. The inference-run may be hosted on-premise or at a remote server.

A prompt may be understood as a piece of text or input data that is used to initiate the generation of output by the LM.

This arrangement allows for iterative prompting of the LM, enabling finer control over the generated output and allowing for more precise refinement of the results. An effect of this is that the quality of the generated output may be improved through repeated iterations, with each iteration providing an opportunity to fine-tune the output based on the previous result.

In an example, each iteration may include validating an output of an LM.

Validating an output of the LM may refer to checking whether the generated control instructions meet certain criteria or requirements. Validating may be based on another model, such as another LM different to the LM that has generated the control instructions. Alternatively or additionally, validating may be based on a blacklist or whitelist of control instructions or pieces thereof. One or more predefined heuristic rulesets may be used for validating. Validating may include a comparison of the output of the LM against information included in the user query. For instance, validating may include checking whether the output of the LM includes information answering questions raised in the user query. Validating may include whether the output of the LM triggers certain blacklisted actions or triggers actions that may damage the lithography-process inspection tool (so-called “jailbreaks”). Validating may include checking that the output of the LM fulfills certain syntactic rules that are predefined.

This arrangement enables avoiding creating control instructions that may damage the tool or compromise safety. By incorporating validation into each or at least some iterations, the system can refine its outputs and produce high-quality control instructions that meet safety standards while minimizing the risk of errors or omissions.

In an example, each iteration may include validating an output of an LM. Based on said validating, a subsequent iteration may be selectively triggered.

This arrangement enables control instructions to be refined iteratively until they meet the desired standards. This iterative refinement process allows for a feedback loop between the LM and the validation mechanism, enabling the LM to learn from its mistakes and improve the control instruction from iteration to iteration.

In an example, validating may be based on a respective one of the at least one LM. The LM used for validating the control instructions may be a different LM than the language model used for generating the control instructions.

An effect of this is that high-quality control instructions can be generated through the use of diverse LMs. These models may be competing in the generation of control instructions. Mistakes by one LM can be identified by the other LM.

In an example, validating may be based on a digital twin of the lithography-process inspection tool.

A digital twin may be understood as a virtual replica of a physical system or process. In the present case, it may refer to a virtual representation of the lithography-process inspection tool. It can be determined whether a certain control instruction would result in unsafe behavior of the tool. To give a concrete example: a virtual replica of an actinic microscope may refer to a digital twin that simulates EUV mask-inspection performance around 13.5 nm. The model may include rigorous coupled-wave analysis and frequency-domain finite-element methods for multilayer and absorber diffraction, while finite-difference time-domain may be used for broadband or transient electromagnetic effects. Image formation may be treated with Fourier-optics formalisms (Abbe/Hopkins), including partial-coherence transfer. Vectorial focusing and polarization propagation (e.g., Debye-Wolf) may be included, with wavefront propagation by Fresnel or angular-spectrum methods. Aberrations may be described with Zernike polynomials to synthesize point-spread functions. The replica may model source-mask-detector coherence through mutual-intensity or cross-spectral density, account for multilayer Bragg reflectivity of Mo/Si stacks, and include basic stray-light and roughness effects. Noise during acquisition may be represented with Poisson-Gaussian models. Mechanical influences may be captured via stage/vibration modal analysis and simple control-loop co-simulation. Parameter calibration and uncertainty assessment may use standard least-squares or Bayesian inference to align the model with measured data.

For instance, if multiple movable components are controlled by the control instructions, it may be determined whether a collision would occur by executing the control instructions. For instance, the digital twin may also take into account the sample. If a certain exposure of the sample to particles, gases, etc., is defined by the control instructions, it may be determined whether the sample would be damaged or contaminated or altered by such exposure.

This arrangement enables validation of control instructions in a virtual environment before actual roll-out. A kind of “sandboxing” can be enabled, avoiding negative impact on physical reality before validation.

In an example, a respective prompt in a given iteration of one or more iterations may be generated further based on a compressed representation of at least a part of the tool context data and optionally sample context data associated with the sample.

A compressed representation refers to a condensed form of the original data that still captures its essential features. In this case, the compressed representation may be obtained by applying a machine-learning encoder to extract latent features from the tool context data and/or the sample context data. These latent features are lower-dimensional representations of the original data that capture its underlying machine-learned patterns and relationships. The use of a machine-learning encoder allows for the automatic discovery of complex patterns in the data, which may not be apparent through manual analysis. The resulting compressed representation provides a more compact summary of the data, enabling the generation of more accurate and informative prompts.

This arrangement enables the use of retrieval-augmented generation (RAG) techniques, which combines the strengths of traditional information retrieval systems with the generative capabilities of LMs. RAG is a framework that allows for the incorporation of external knowledge (here, the tool context data and/or sample context data) into the text generation process (here: of the control instruction). RAG works by retrieving relevant information from external sources, augmenting the prompt with this information, and then generating new text based on the combined context. By leveraging external knowledge bases and augmenting user queries with relevant information, RAG can produce more accurate and informative responses. An effect of this is that high-quality control instructions can be generated quickly and efficiently, reducing the time and effort required for control instruction development.

Several variations can be employed to provide context information to the LM. RAG is only one option. A simpler variation is to directly append context information (e.g., tool and/or sample context information) in the prompt. However, this requires sufficiently long context windows (context windows define the maximum possible length of the prompt) or separate techniques for increasing the prompt length. Thus, such approach of directly appending the context information may not be usable due to restricted context-length of the prompts. Another approach is to fine-tune the LM with historical data. This can make the LM aware of task-specific details without needing longer prompts or RAG techniques. However, this approach has drawbacks such as large fine-tuning costs and would need to be done whenever the “historical data” or the manual changes.

In an example, a respective prompt in a given iteration of one or more iterations may request at least one LM to access tool context data and/or sample context data associated with the sample.

This arrangement enables the incorporation of relevant knowledge into the control instruction generation process. By requesting access to this external information, the LM acts as an agent, proactively seeking out relevant knowledge to inform its control instruction generation. This enables the LM to generate more relevant and effective control instructions.

In an example, generating control instructions may include multiple iterations. In a given iteration of these multiple generations, a respective prompt may be generated based on feedback on an output of an LM in a preceding iteration and/or based on the respective prompt of the preceding iteration.

Feedback may include user feedback such as user ratings, corrections, or suggestions. This feedback may be used to adjust the prompt for the next iteration, allowing the LM to learn from its mistakes and improve its performance. Feedback may also be provided, e.g., automated, e.g., from a competing LM or a heuristic quality metric. Feedback may be obtained from a model (e.g., another LM) used for validating the control instructions, as previously discussed.

These techniques allow the LM to build upon its previous work, incorporating knowledge and insights gained in earlier iterations into its subsequent outputs.

In an example, multiple output variants are generated and then the multiple output variants are evaluated for consistency using a respective LM. This approach enhances the overall quality of the generated control instructions while also allowing for the derivation of a form of “uncertainty” from the variability of the output variants. The output variants can be generated either by employing different LMs or by performing multiple inference operations on a single LM with a probabilistic component in text generation, which may be technically controlled by the temperature parameter in beam search (with temperatures close to 0 resulting in less variability and temperatures greater than 1 resulting in more variability).

Human operator interaction can be incorporated into the iterative process. This allows a human expert to review and refine the control instruction suggestions provided by the LM, reducing the likelihood of non-fitting or incorrect control instructions. For instance, an expert can assess the plausibility of the suggested control instructions and optionally edit them as needed. Additionally, the expert can interact with the LM through natural language queries, such as “Find alternatives for step 5 that allow for more robust detection of small defects.” This human verification and interaction element reduces the probability of poor-quality control instructions being generated. Thus, a user interface may be provided that enables a human expert to review, refine, and interact with the control instruction suggestions provided by the LM.

This arrangement enables user-interactive refinement of control instruction generation by the LM. An effect of this is that high-quality control instructions can be generated through an iterative process of feedback and refinement, allowing users to guide the LM towards producing optimal results.

Next, some general observations on the control instructions obtained from the generative AI disclosed herein are discussed.

The control instructions may specify one or more parameters for operating the lithography-process inspection tool, e.g., including imaging parameter values that define how the sample is imaged. For example, an imaging parameter value may include a setting for the illumination intensity, wavelength, or numerical aperture of the imaging system.

For instance, a field of view to be imaged may be set by use of the control instructions. This may be based on sample context data. For instance, typically samples in a lithography processes—e.g., wafers or lithography masks—include multiple types of different structures. Sometimes, depending on the user query, imaging of certain regions of the sample including a given type of structures may be prioritized over scanning the entire sample, e.g., to minimize the time required for completing the image acquisition. For instance, for a mask defining a system-on-chip, certain regions of the system-on-chip may be of interest for a particular task specified by the user query; while other regions of the system-on-chip may not be of particular interest. The particular regions of interest can be extracted based on sample context data, e.g., by relying on respective geometrical information on the arrangement of the various types of structures.

The control instructions may specify an image analysis algorithm that is used to analyze the imaging data acquired using the lithography-process inspection tool. This algorithm may include techniques such as thresholding, edge detection, or feature extraction. Anomalies may be detected. Such algorithms may include techniques such as segmentation, which involves partitioning an image into distinct regions or features of interest. Detection may be used to identify specific patterns, anomalies, or defects within the imaged sample. Classification may involve categorizing detected features based on predefined criteria, such as defect types or severity levels. Measurement may refer to quantifying attributes of the sample, such as critical dimensions, line-edge roughness, or other structural properties. Registration may involve aligning multiple images or datasets to a common reference frame for comparative analysis. Localization may focus on determining the precise position of specific features within the sample. Metrology refers to the measurement and characterization of physical properties, such as critical dimension uniformity or overlay accuracy. Verification processes may ensure that the analyzed data meets specified standards or tolerances.

Another example pertains to the selection of a registration algorithm from multiple candidates. This may depend on, e.g., the particular shape or geometry of the imaged structures. For instance, there may be registration algorithms that are optimized for 1-D patterns (e.g., “lines and spaces”); while there may be other registration algorithms that are optimized for 2-D patterns. Certain registration algorithms may be more suitable for die-to-die registration; while other registration algorithms may be more suitable for die-to-database registration.

Alternatively or additionally to the control instructions specifying the image analysis algorithm, the control instructions may specify one or several parameters of a given image analysis or processing algorithm. For instance, the control instructions may specify a parameter that defines the tolerance for detecting defects. By appropriately setting this parameter, tailoring a tradeoff situation between (i) detecting only clear defects effects at a low count of false positives and (ii) ensuring that any defect is detected at a high count of false positives. Depending on the user query, e.g., depending on whether the user emphasizes a need for high accuracy or high tolerance, the control instructions may be appropriately generated by the LM. The control instructions for operating a lithography-process inspection tool may accordingly specify parameters of image analysis algorithms for defect detection. For example, these parameters may define defect detection tolerances, allowing a tradeoff between minimizing false positives and ensuring comprehensive defect detection. Depending on the user query, which may emphasize high accuracy or tolerance, the control instructions can be generated by a LM. This approach simplifies generating control instructions for lithography-process inspection tools compared to prior art methods.

The control instructions may also include one or more branching positions that define conditional logic for executing different control branches based on ad-hoc decision criteria. For instance, If-Then clauses can be included. These decision criteria may be based on the results of image analysis, sensor data from the lithography-process inspection tool, or other input parameters determined while executing the inspection process. Example if-this-then-that clauses may include, e.g., checking, for an SEM, whether the signal-to-noise ratio in acquired images falls below a certain predefined threshold; if this is observed, then the dwell time used when scanning across the sample may be increased. Alternatively or additionally, if this is detected, then the beam current may be increased. For an actinic microscope, such if-this-then-that branching positions may include increasing the exposure dose if the contrast falls below a certain contrast. For atomic-force microscopy control instructions, such if-this-then-that branching positions may include introducing a probe retract cycle, pausing the scanning and recalibrating the probe tip, if certain artifacts in the frequency response of the tip are being observed. These are only examples but illustrate how branching positions can be used to define conditional actions, depending on certain circumstances observed during execution of the control instructions.

Furthermore, the control instructions may specify one or more event-triggered control items that are executed in response to specific events or conditions occurring during the operation of the lithography-process inspection tool. The events or conditions that trigger event-triggered control items in a lithography-process inspection tool can be diverse and depend on the specific requirements of the lithography process, the design of the tool, and the characteristics of the sample being inspected. For example, detection of defects such as particles, scratches, or other anomalies on the sample surface may require adjustments to the inspection parameters, e.g., to zoom into an area suspected to include a defect or to resolve defect properties. Changes in environmental conditions like temperature, humidity, or pressure within the tool's operating environment may also necessitate adjustments to the inspection process. Completion of a measurement cycle can trigger analysis of the data collected during that cycle, storage of the results, or initiation of additional measurements.

Next, some general aspects of the user query will be discussed.

The user query may include detailed information about the desired task, specifying one or more elements that guide the generation of control instructions. For example, the user query may specify an imaging parameter value for the lithography-process inspection tool, such as the intensity of illumination or the resolution of the imaging system, to optimize the acquisition of imaging data from the sample. Alternatively, the user query may define an image analysis algorithm to be applied to the acquired imaging data, such as a defect detection algorithm or a feature extraction algorithm, to extract relevant information from the data.

Alternatively or additionally, the user query may specify a defect type for a defect detection task, indicating the specific type of defect that needs to be detected, such as scratches, particles, or other anomalies. The user query may also provide information about the type of sample being inspected, including its material properties and dimensions, to ensure that the control instructions are tailored to the specific sample characteristics.

In some cases, the user query may include a time constraint for the task, specifying the maximum amount of time available for completing the inspection task. This information can be used to optimize the control instructions and minimize the inspection time while maintaining the required level of accuracy.

Furthermore, the user query may impose restrictions on deviating from one or more reference control instructions, ensuring that any modifications to the control instructions are within predetermined limits. This feature allows users to maintain consistency in their inspection processes while still allowing for flexibility and adaptability.

Finally, the user query may define a repair strategy for a repair task, specifying the steps required to correct defects or anomalies detected during the inspection process. This information can be used to generate control instructions that implement the desired repair actions.

In an example, a method may further comprise obtaining information on a reasoning associated with control instructions from at least one LM. This arrangement may provide increased trust levels in the generated control instructions.

Obtaining this information may allow to understand how the LM arrived at the generated control instructions, which can be used as input to validation of the control instructions.

In an example, the obtained information on the reasoning associated with the control instructions may include pointers to at least sections of one or more reference control instructions.

This arrangement may enable users or models to directly compare the generated control instructions with established reference control instructions, which can lead to improved trust and reliability in the generated control instructions.

To further enhance transparency and reproducibility, variants such as “explain a logical chain-of-thought step by step” are possible. This approach enables the LM to provide a detailed explanation of its reasoning process in generating the control instructions, allowing users or models to understand how the control instructions were generated.

The benefits of this approach include increased transparency and reduced likelihood of non-fitting control instructions. By providing a clear and logical chain-of-thought, the LM can demonstrate its decision-making process, which can lead to improved trust and reliability in the generated control instructions.

The information on the reasoning associated with the control instructions may be provided in various formats, including free-text format, which is understandable by humans, or as a feature vector, which includes machine-learned features. The free-text format allows users to easily comprehend the reasoning behind the generated control instructions, while the feature vector format enables further processing and analysis of the information, for example, as input to a validation model (e.g., another LM, as discussed above). For instance, if the information on the reasoning is provided in free-text format, it may include natural language text that explains why certain parameters were chosen or how specific conditions were evaluated. On the other hand, if the information is provided as a feature vector, it may include numerical values representing machine-learned features, such as semantic embeddings or predictive probabilities, which can be used to analyze and validate the generated control instructions.

In an example, the method may further include fine-tuning of the at least one LM based on reference user queries and reference control instructions. This arrangement may enable the LM to learn from feedback gathered during the generation of context information.

Fine-tuning the LM may involve using the reference user queries and reference control instructions as ground truth data, which can be stored and utilized to improve the accuracy of the context information provided by the LM.

Fine-tuning a pre-trained LM involves adjusting its weights to adapt to new data, such as reference user queries and associated control instructions. Weights may include all parameters of the LM that are set using a machine-learning process, e.g., backpropagation or another optimization technique that minimizes a loss of the output of the pre-trained LM against ground truth. This process starts with the existing weights of the LM, which serve as an initialization point. The fine-tuning process may, e.g., employ backpropagation to compute the gradients of a loss function, which measures the difference between the LM's predictions and the ground truth data. By iteratively updating the weights in the direction of the negative gradient, the LM learns to minimize the loss function and adapt its weights to better fit the new data.

An effect of this arrangement is that the LM learns to provide inherently better context information over time. A further effect of this arrangement is that a tool-specific instance of the LM may be obtained from the fine-tuning process. This means that the resulting LM instance is tailored to the specific requirements and constraints of a particular tool or application, allowing for even more accurate and reliable results in that context.

An electronic data processing device, e.g., a personal computer, a server, a cloud server, a cloud-server cluster, etc., is disclosed. The electronic data processing device includes a processor and a memory. The processor is configured to load program code from the memory and execute the program code. The processor, upon loading and executing the program code, performs a method as disclosed above. A program code is disclosed. The program code can be loaded and executed by a processor. The processor, upon loading and executing the program code, performs a method as disclosed above.

It is to be understood that the features mentioned above and those yet to be explained below may be used not only in the respective combinations indicated, but also in other combinations or in isolation without departing from the scope of the invention.

### DESCRIPTION OF DRAWINGS

FIG. 1 is a flowchart of a method according to various examples.

FIG. 2 schematically illustrates an electronic data processing device according to various examples.

### DETAILED DESCRIPTION

Some examples of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a graphics processor unit (GPU), a tensor processing unit (TPU), integrated circuits such as application-specific integrated circuits or field-programmable gate array (FPGA) circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the invention will be described in detail with reference to the accompanying drawings. It is to be understood that the following description of embodiments is not to be taken in a limiting sense. The scope of the invention is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Various techniques disclosed herein are concerned with using generative artificial intelligence for determining control instructions for lithography-process inspection tools. In particular, various examples use machine-learning models, in particular LMs, to automate the determination of control instructions. Various tasks associated with samples such as a wafer or a lithography mask may be achieved by the control instructions. The control instruction may define how to inspect a specific mask layer or pattern on a semiconductor wafer. Some disclosed techniques include the creation of defect detection control instructions for lithography-process inspection tools.

Example lithography-process inspection tools include but are not limited to those mentioned in TAB. 3.

TABLE 3
Example of lithography-process inspection tools. A lithography-
process inspection tool may acquire imaging data of the
sample, i.e., a visual representation of the sample.

| | |
|---|---|
| Actinic | An actinic microscope is a type of optical |
| Microscope | microscope that uses light or generally |
| | electromagnetic radiation to inspect |
| | lithography masks. |
| | The actinic microscope uses illumination |
| | radiation with a wavelength that corresponds |
| | to the wavelength that is intended for |
| | structuring a wafer when the mask is used in |
| | a projection exposure system at a later stage. |
| Scanning Electron | A SEM is an electron microscope that uses |
| Microscope | one or more focused beams of electrons to |
| (SEM) mask | produce high-resolution images of wafer |
| repair tool | surfaces or mask surfaces. It works by |
| | scanning the electron beam across the |
| | surface of the wafer or mask or generally the |
| | sample, detecting secondary electrons |
| | emitted from the sample, and creating |
| | detailed images of the surface topography. |
| | Process gasses can be introduced for |
| | manipulation tasks, e.g., chemical vapor |
| | deposition, gas-phase etching, or |
| | nanoparticle formation. |
| SEM-FIB- | A SEM-FIB-crossbeam tool is a |
| Crossbeam Tool | combination of a SEM and a focused ion |
| | beam (FIB) column. It works by using the |
| | electron beam to image the sample while |
| | simultaneously using the FIB to mill or |
| | deposit material on the surface, allowing for |
| | precise manipulation and thus allows for |
| | layer-by-layer imaging of the sample. |
| Atomic Force | An Atomic Force Microscope (AFM) |
| Microscope | operates by using a sharp probe attached to a |
| | cantilever beam that scans over the surface |
| | of a sample, detecting changes in height and |
| | composition. As the probe interacts with the |
| | sample's surface, it is deflected, causing the |
| | cantilever beam to bend, which is then |
| | measured using laser light reflected off the |
| | back of the cantilever. The measured |
| | deflections are used to create detailed |
| | topographic images of the sample's surface |
| | at the nanoscale. |

This disclosure describes techniques that provide improvements to the functioning of lithography-process inspection and/or repair tools. In some implementations, an improved actinic microscope is provided in which the actinic microscope includes an electronic data processing device that provides a user interface to allow a user to enter a user query in a format that is user-friendly (e.g., in a free-text format). The electronic data processing device converts the user query to a prompt that is provided to a pre-trained model which outputs control instructions for controlling the actinic microscope. This allows a user who may not have expert knowledge of the operation of the actinic microscope to still be able to use the actinic microscope to carry out a lithography-process inspection. For example, the user may enter a user query “determine line roughness of “line and spaces” patterns on lithography mask” and the electronic data processing device converts the user query to a prompt—e.g., including task instructions determined based on this user query, knowledge-retrieval instructions for RAG, formatting instructions, positive and/or negative examples, and/or role instructions—that is provided to the pre-trained model which outputs control instructions for controlling the actinic microscope. The control instructions may, in particular, define one or more properties of time-delayed imaging modes, e.g., a stage speed, speed and/or other properties of a swath scanner that is employed, and/or an overlap of the time-delayed imaging regions. A swath scanner is a scan architecture where a long, narrow strip (“swath”) of the mask is imaged onto a time-delayed imaging line-scan detector, wherein the mask is moved continuously under that strip. The detector shifts charge in sync with the stage motion to integrate each point along the scan without blur. After finishing one pass, the stage steps orthogonally and repeats on the next adjacent strip, tiling swaths to cover the full mask. In many EUV actinic systems, multiple modules are tiled to make a wider swath and higher throughput, then interleave/overlap swaths if needed for 100% coverage. Additionally or alternatively, postprocessing properties may be set. For instance, certain postprocessing algorithms—e.g., denoising, re-focusing, de-jittering, super-resolution, to give just a few examples—may be used in order to process acquired images prior to applying a further analysis algorithm, e.g., to detect defects. The particular analysis algorithm used, e.g., to detect defects or determine certain sample properties may be specified by the control instructions. For instance, a selection may be made between a machine-learning-based image analysis algorithm on the one hand and a heuristics-based image analysis algorithm on the other hand. These and other properties may be set by the control instructions. The user may not know the details of the parameters specified in the prompt, and may not know the commands specification in the control instructions, and may still operate the actinic microscope to perform the desired lithography-process inspection. This provides a significant improvement over conventional actinic microscopes that typically requires a user to have a high level of relevant expertise.

In some implementations, an improved scanning electron microscope mask repair tool is provided in which the scanning electron microscope mask repair tool includes an electronic data processing device that provides a user interface to allow a user to enter a user query in a format that is user-friendly (e.g., in a free-text format). The electronic data processing device converts the user query to a prompt that is provided to a pre-trained model which outputs control instructions for controlling the scanning electron microscope mask repair tool. This allows a user who may not have expert knowledge of the operation of the scanning electron microscope mask repair tool to still be able to use the scanning electron microscope mask repair tool to carry out a repair process. For example, the user may enter a user query “Image all memory trenches” and the electronic data processing device converts the user query to a prompt that is provided to the pre-trained model which outputs control instructions for controlling the scanning electron microscope mask repair tool. The prompt may, in particular, include a free-text description of the sample under investigation, e.g., a memory die. In the free-text description of the sample, regions of the sample may be quantitatively located, e.g., in a sample coordinate system. These region may pertain to different parts of the sample and one particular region may include memory trenches. Then, the control instructions may include certain control parameters for the field of view of the SEM as well as stage positions for imaging that ensure that all memory trances are being imaged; while other regions or surrounding parts of the sample may be excluded from imaging. The user may not know the details of the parameters specified in the prompt, and may not know the commands specification in the control instructions, and may still operate the scanning electron microscope mask repair tool to perform the desired repair process. This provides a significant improvement over conventional scanning electron microscope mask repair tools that typically requires a user to have a high level of relevant expertise.

In some implementations, an improved SEM-FIB-crossbeam tool is provided in which the SEM-FIB-crossbeam tool includes an electronic data processing device that provides a user interface to allow a user to enter a user query in a format that is user-friendly (e.g., in a free-text format). The electronic data processing device converts the user query to a prompt that is provided to a pre-trained model which outputs control instructions for controlling the SEM-FIB-crossbeam tool. This allows a user who may not have expert knowledge of the operation of the SEM-FIB-crossbeam tool to still be able to use the SEM-FIB-crossbeam tool to carry out precise manipulation of a sample and layer-by-layer imaging of the sample. For example, the user may enter a user query “perform a trench cut” and the electronic data processing device converts the user query to a prompt that is provided to the pre-trained model which outputs control instructions for controlling the SEM-FIB-crossbeam tool. The ion beam current, ion spot size, etc. may be set, e.g., based on material properties of the sample. For instance, if subsequent tunnel-electron imaging is desired, the milling properties may be set in accordance with certain requirements of the downstream tunnel-electron imaging. The user may not know the details of the parameters specified in the prompt, and may not know the commands specification in the control instructions, and may still operate the SEM-FIB-crossbeam tool to perform the imaging process. This provides a significant improvement over conventional SEM-FIB-crossbeam tools that may typically requires a user to have a high level of relevant expertise.

In some implementations, an improved atomic force microscope is provided in which the atomic force microscope includes an electronic data processing device that provides a user interface to allow a user to enter a user query in a format that is user-friendly (e.g., in a free-text format). The electronic data processing device converts the user query to a prompt that is provided to a pre-trained model which outputs control instructions for controlling the atomic force microscope. This allows a user who may not have expert knowledge of the operation of the atomic force microscope to still be able to use the atomic force microscope to generate detailed topographic images of a sample's surface at the nanoscale. For example, the user may enter a user query and the electronic data processing device converts the user query to a prompt that is provided to the pre-trained model which outputs control instructions for controlling the atomic force microscope. The user may not know the details of the parameters specified in the prompt, and may not know the commands specification in the control instructions, and may still operate the atomic force microscope to perform topographic imaging. This provides a significant improvement over conventional atomic force microscopes that typically requires a user to have a high level of relevant expertise.

Next, one specific implementation of an example method is disclosed. To improve the accuracy and efficiency of automated generation of control, it is possible to leverage “good” and “bad” control instructions from past experiences. A “good” control instruction refers to a control instruction that has been successfully used in the past to detect defects on a specific mask layer or pattern, while a “bad” control instruction refers to a control instruction that did not produce satisfactory results. To create new control instructions, task-specific information may be gathered, such as the type of mask layer being inspected, the desired focus conditions, and the types of defects to be detected. This information is typically provided in the form of a prompt from the user. An example task-specific information would be: “Sample under inspection is a mask layer for printing contact holes at a focus-20 nm; find all protrusion defects; feature size is 30 nm and process the whole mask in 6 hours. The tool was already running for 2 years.” Next, retrieval-augmented generation (RAG) technique may be used to consolidate this task-specific information with relevant knowledge extracted from the system manual and past control instructions. RAG is a machine learning approach that involves retrieving relevant information from a database or knowledge base and using it to augment a user-provided prompt. The augmented prompt is then passed to a LM, which generates a proposed control instruction based on this input. Finally, the proposed control instruction may be used on the preferred inspection system, e.g., to detect defects on the semiconductor wafer. The advantages of this approach include reducing the time required to create a useful control instruction proposal, reducing the risk of poor control instruction proposals, and enabling less experienced personnel to create high-quality control instructions.

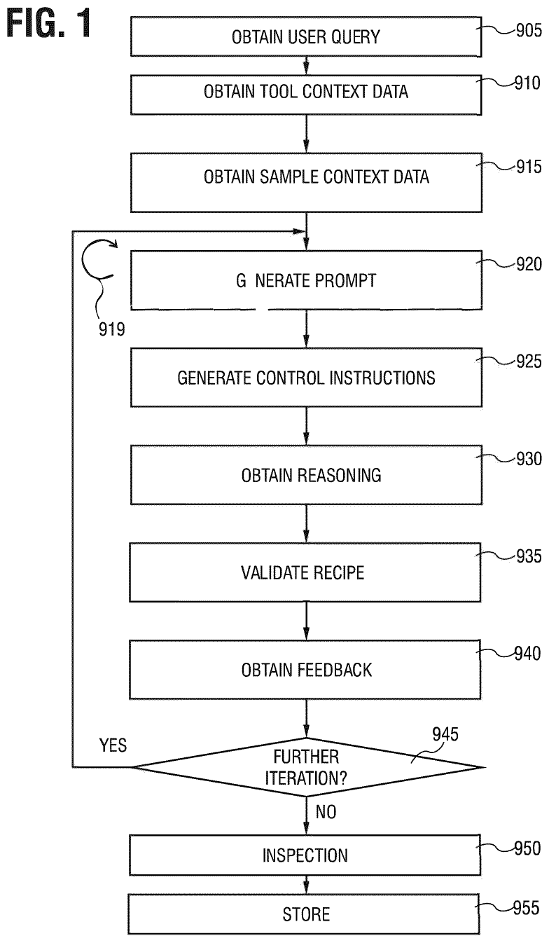

FIG. 1 is a flowchart of a method according to various examples. The method of FIG. 1 pertains to generating control instructions for operating a lithography-process inspection tool (cf. TAB. 3). The method of FIG. 1 employs generative artificial intelligence for generating the control instructions. More specifically, a LM is used to generate the control instructions, e.g., in the form of script code. The lithography-process inspection tool is operating for inspecting a sample such as a semiconductor wafer or a lithography mask.

At box 905, a user query is obtained. The user query may be in free-text format. The user can thereby specify a task to be carried out by the lithography-process inspection tool on a sample, e.g., on a wafer or lithography mask. The user query can specify an imaging parameter value of the lithography-process inspection tool, an image analysis algorithm, a defect type, type of the sample, time constraint of the task, a restriction for deviating from one or more reference control instructions, and/or a repair strategy of a repair task. These are only examples.

At box 910, it is optionally possible to obtain tool context data. The tool context data may include prior knowledge on operation of the lithography-process inspection tool. For instance, the tool context data may be loaded from a database or may be retrieved from a control unit of the lithography-process inspection tool. Examples of tool context data include an operating manual of the lithography-process inspection tool, reference control instructions for the task specified by the user query and/or one or similar tasks or other tasks, possibly accompanied by labels indicating positive and negative reference control instructions, and operational status of the lithography of process inspection tool, and operational history of the lithography-process inspection tool, a fault indicator of the lithography-process inspection tool, tool metadata and/or sensor data associated with the lithography-process inspection tool.

As a general rule, the reference control instructions may not be available for the specific task defined by the user query. For instance, the user query may define a task of determining defects in a “line and spaces” pattern of semiconductor structures having a periodicity of 80 nanometers (e.g., as apparent from sample context data). A database of reference control instructions may be available in which detection of similar defects has been successfully implemented for a “lines and spaces” pattern having periodicity of 70 nanometer and for a further “lines and spaces” pattern having a periodicity of 90 nanometers (but not for 80 nm periodicity). Then, based on these adjacent positive reference control instructions, the LM may be able to determine control instructions for the particular task at hand, e.g., concluding which particular parameter settings may be particularly suitable for this task at hand. For instance, interpolation or projection techniques may be used by the LM.

Next, to illustrate the concepts of positive and negative reference control instructions, two specific examples are provided. Positive reference control instructions and negative reference control instructions are exemplified for the task of imaging a polished cross-section of a multiphase Ni-based superalloy. The goal of such a task often involves maximizing compositional contrast for different phases of such Ni-based superalloy, specifically mean-atomic-number contrast, rather than surface relief. To achieve this objective, in positive reference control instructions, certain detector settings and operating parameters may be employed. For instance, the use of a backscattered electron detector is advantageous as it provides strong mean-atomic-number contrast between different phases. An accelerating voltage in the range of 15-20 kV may be utilized to ensure a deeper interaction volume and robust backscattered electron yield. This setting also complements energy-dispersive spectroscopy if spot-checking of phases is required. The probe current may be set to a moderate level, such as between 1-5 nA, depending on the specific instrument capabilities. This range helps achieve a good signal-to-noise ratio for BSE imaging without causing excessive beam-induced sample degradation or bloom. In contrast, a negative reference control instruction may use certain settings and approaches that are less effective or even counterproductive for this task. For example, using a secondary electron detector instead of backscattered electron detector may emphasize surface topography rather than composition, potentially leading to misinterpretation of phase distribution on a polished sample. Low accelerating voltages in the range of 1-3 kV can diminish backscattered electron detector signal intensity, making it challenging to distinguish between different phases based solely on faint relief features. Both examples may be provided to the LM to enable construction of the most appropriate control instruction.

As will be appreciated from the above, it is possible to provide sample-specific context data that indicates a material of the sample under investigation and then provide control instructions for the lithography-process inspection tool that are tailored to this particular material.

At box 915, it is optionally possible to obtain sample context data. The sample context data may include prior knowledge on the sample.

For example, the sample context data may include imaging data of the sample and/or reference imaging data of a reference sample. For instance, the reference sample may be of similar type as the sample under investigation. The sample context data may include a feature representation, e.g., of machine-learned features, of the imaging data and/or the reference imaging data.

Alternatively or additionally, the sample context data may include a free-text-description of one or more properties of the sample, e.g., obtained from a user via a user interface. The sample context data may include a process history of a fabrication process for obtaining the sample and/or an aging status of the sample.

Next, a loop including one more iterations 919 is entered. At box 920, a prompt is generated. The prompt may be generated based on the user query 905 and optionally based on the tool context data and/or the sample context data obtained at box 910 and box 915, respectively. For instance, a prompt-generation model may be used. This may be a LM. It would also be possible to use predefined prompt parts and include the user query at respective sections.

Such prompt part may be a predefined textual element that can be combined with other such elements to form a complete prompt for triggering an inference-run of a language model. The use of prompt parts allows for modular and flexible construction of prompts by enabling the combination of different pre-defined components tailored to specific tasks or contexts. In some examples, a prompt part may be stored in a library of predefined prompt segments. Such library may include a variety of reusable textual elements that correspond to different aspects of a task or context. For instance, one prompt part may relate to the definition of imaging parameters for a lithography-process inspection tool, while another may pertain to defect detection criteria. A predefined prompt structure may be used to organize and combine these prompt parts in a systematic manner. This structure may define how different prompt parts are sequenced or formatted within the overall prompt, ensuring that the resulting input to the LM is coherent and effective. For example, a system prompt may provide general contextual information about the lithography-process inspection tool, while task-specific prompt parts may detail the particular requirements of the user query. Such separation of context and task in prompt parts allows for clear distinction between general operational knowledge and specific instructions tied to a particular objective. This arrangement enhances the effectiveness of the prompts, enabling the LM to generate more accurate and relevant control instructions.

The prompt may incorporate a compressed representation, e.g., a feature embedding, of or associated with the tool context data and/or the sample context data. RAG may be employed to do so. For instance, a prompt may comprise a natural-language description of the task to be performed, combined with a vector representation derived from tool context data or sample context data. Such a vector representation could be a feature embedding generated using a machine-learning model trained on a dataset specific to lithography-process inspection tools or samples. For example, the prompt might state: “Generate control instructions for inspecting a semiconductor wafer using an actinic microscope at a wavelength of 193 nm, incorporating the following tool context features: [embedded vector representing SEM operational history].” An LM may be inferred to obtain the compressed representation. Alternatively or additionally, it would be possible to generate the prompt so that it requests the LM to access the tool context data and/or the sample context data, e.g., provisioned at a certain storage location. To generate a prompt that requests a LM to access tool context data or sample context data provisioned at a certain storage location, the prompt may include natural-language directives instructing the LM to reference specific files or databases. For example, the prompt might state: “Generate control instructions for inspecting a lithography mask layer, taking into account operational history data stored in ‘tool_context.db’ and imaging data from ‘sample_123.dat’.” Alternatively, the prompt could specify that the LM should retrieve feature embeddings from a designated storage location, such as “incorporate feature embeddings of SEM sensor data located at ‘/path//embeddings.csv’ when generating control instructions for this task.”

Thus, the LM can act as an agent, retrieving the respective context information on as-needed basis. At box 925, an inference run of the LM to generate the control instructions is triggered. The LM may be locally inferred or may be inferred at a server. the inference run of the LM is triggered based on the prompt generated at box 920.

As an output of box 925, the control instructions are obtained. At box 930, it would be possible to obtain, from the LM, information on the reasoning associated with the control instructions.

For instance, pointers to sections of one or more reference control instructions, e.g., as provided as part of box 910, may be included in such information on the reasoning. Also, a chain-of-thought may be provided. Such chain-of-thought (Cot) may be based on so-called scratchpad rationales where intermediate reasoning steps are stored and considered during the generation process/inference of the LM. This approach can be combined with few-shot CoT prompting, which uses example demonstrations to guide the reasoning process. Self-consistency may be achieved through techniques such as majority vote among multiple LMs or iterations, ensuring that the generated output aligns with a consensus. Process reward models may be employed to reward the generation of coherent and logical reasoning steps during the chain of thought process, while outcome-supervision (answer-only) focuses on evaluating the correctness of the final result rather than the intermediate reasoning. Rejection sampling (rationale filtering) may involve discarding outputs that fail to meet certain criteria, such as generating invalid rationales or illogical steps. Verifier-guided decoding can be used to evaluate and refine the generated content in real-time, ensuring that the chain of thought adheres to predefined constraints or requirements. The chain of thought concept can thus encompass a variety of techniques aimed at improving the transparency, consistency, and quality of reasoning processes.

The control instructions may be indicative of an imaging parameter value of an imaging task to be executed by the lithography-process inspection tool. Alternatively or additionally, the control instructions may be indicative of an imaging analysis algorithm for analyzing imaging data that is acquired using the lithography-inspection tool, e.g., using the imaging mentioned above. The control instructions may also be indicative of one or more branching positions for branching between different control branches for controlling the lithography-process inspection tool, e.g., depending on one or more at-hoc decision criteria to be checked during the inspection process. One or more event-trigger control items may be specified by the control instructions.

Various examples of control instructions for lithography-process inspection tools are provided below. These examples illustrate how different imaging parameters, analysis algorithms, branching positions, and event-trigger control items may be specified for different tools. Note that the specific quantitative properties and settings are not limiting but are used to illustrate the concepts of comprehensive control instructions to set imaging and/or post-imaging data processing.

In a first example, SEM control instructions (cf. TAB. 3) may include imaging parameters such as setting the accelerating voltage to 3 kV, beam current to 50 pA, working distance to 4 mm, pixel size to 2 nm, scan dwell time to 2 microseconds, and frame averaging count to 4. The imaging analysis algorithm may involve running contour extraction and critical dimension metrology on line-space patterns at the field center and four corners, and computing line edge roughness and pattern placement error relative to the design. Branching positions may include, for example, increasing dwell time to 3 microseconds if the signal-to-noise ratio falls below 12 dB, enabling low-kV drift correction and reducing beam current to 30 pA if charging artifacts are detected via histogram skew, or triggering a high-magnification rescan at 1 nm pixel size if overlay error exceeds 5 nm. Event-trigger control items may include vacuum health checks if chamber pressure rises above 5e-6 Torr, re-acquiring the image if stage vibration exceeds 5 nm RMS during scanning, or stopping and notifying if beam drift exceeds 10 nm over 60 seconds.

In a second example, actinic microscope control instructions (cf. TAB. 3) may specify imaging parameters such as setting illumination wavelength to 13.5 nm, numerical aperture to 0.33, partial coherence to 0.2, exposure dose to a nominal value D, field of view to 50 micrometers by 50 micrometers, and pixel sampling to 10 nm. The imaging analysis algorithm may involve executing aerial image reconstruction and phase defect detection using Fourier filtering, computing image contrast and phase shift of detected defects, and classifying defects based on amplitude and location relative to absorber edges. Branching positions may include increasing exposure dose by 10 percent if aerial image contrast falls below 0.3, performing a fine focus stack with offsets of −50 nm, 0 nm, and +50 nm if phase defect amplitude exceeds 2 percent, or conducting a localized high-resolution scan at 5 nm sampling if edge placement error relative to the mask design exceeds 3 nm. Event-trigger control items may include recalibrating the tool if source power fluctuation exceeds 2 percent during a field, aborting and flagging the process if detector count rate saturation exceeds 1 percent of pixels, or performing an environmental check if temperature drift exceeds 0.2 degrees Celsius over 5 minutes.

In a third example, atomic-force microscopy control instructions (cf. TAB. 3) may define imaging parameters such as tapping mode with drive frequency at resonance minus 50 Hz, free amplitude of 30 nm, setpoint amplitude ratio of 0.8, scan rate of 0.5 lines per second, pixel size of 5 nm, and medium z-feedback gain. The imaging analysis algorithm may include surface topography extraction and line profile metrology across resist features, computing step height, line width, and sidewall slope, and applying tip deconvolution using a nominal tip radius of 7 nm. Branching positions may involve reducing scan rate to 0.3 lines per second and increasing z-gain if tip-sample interaction causes amplitude drop below 0.7 of the setpoint, switching to denser sampling at 2 nm pixel size if line width variation exceeds 4 nm (3 sigma), or pausing imaging for tip replacement or recalibration if tip wear exceeds a threshold. Event-trigger control items may include pausing and retracting the probe if lateral force estimates exceed limits, auto-reapproaching if engagement is lost for more than 2 seconds, or flagging data integrity if thermal drift exceeds 10 nm per minute.

These examples demonstrate how control instructions for different lithography-process inspection tools may be structured to include imaging parameters, analysis algorithms, conditional branching, and event-triggered actions. Each set of instructions is tailored to the specific capabilities and requirements of the tool (cf. TAB. 3) being controlled.

At optional box 935, it is possible to validate the control instructions output at the current iteration 919 of box 930. For instance, a validation model may be used. This may be another LM or may be a heuristic model not relying on data-driven filter or feature recognition functions. A digital twin of the lithography-process inspection tool may be relied upon.

Such validation models may, in particular, to help avoid risk scenarios associated with operating lithography-process inspection tools. For example, such tools as described in TAB. 3 may benefit from mitigation strategies for specific risk scenarios. As explained above, e.g., an SEM may be used to inspect samples such as wafers or masks by scanning a focused electron beam across the sample surface and detecting secondary electrons emitted therefrom. Risk scenarios associated with SEM operation may include commanding a stage move into a mechanical interference zone, such as when imaging a tall sample at a short working distance under the pole piece. To mitigate this risk, the validation model may employ Z-height clearance verification in simulation or preview may be implemented, along with soft limits and controlled approach speeds. Another SEM-related risk scenario may involve operating with beam conditions or vacuum states outside specification limits, such as turning on high voltage with poor vacuum conditions or during rapid vent/pump cycles. Mitigation strategies for this scenario may include enforcing vacuum interlocks, waiting for stable base pressure before operation (by provisioning the appropriate if-this-then-that clause), and adhering to controlled ramp sequences for high-voltage activation. A third SEM-related risk scenario may involve long, stationary irradiations on charge-prone materials, which could lead to contamination or deposits near the objective lens. To address this, dose limits may be checked by the validation model. An actinic microscope, which uses electromagnetic radiation corresponding to the wavelength intended for wafer structuring during projection exposure, may also benefit from risk mitigation strategies provided by such validation model. For instance, exposing detectors or optics to excessive photon flux or out-of-focus intensity hot spots may be avoided by checking, at the validation model, whether the imaging starts at low source power; this may be based on analysis heuristics. For AFM control instructions, the validation model may check whether there is a risk of tip-sample crashes due to aggressive engagement routines or excessive feedback gain. Height maps for tall topography samples may be accessed by the validation model to do so.

It is optionally possible, at box 940, to obtain feedback on the control instructions obtained from the current iteration 919 of box 930. This feedback may be provided by another LM, different than the LM used for the generative AI process in box 930; it would also be possible to obtain user feedback.

As will be appreciated, in FIG. 1, one or several LMs may be used to solve various tasks. Generally, an LM is suitable to solve various tasks due to its structure and training process. Next, various aspects regarding such LM inference and training that enable to solve the various tasks are disclosed. Generally, the LM may be based on transformer architecture, designed to process and understand text by leveraging self-attention mechanisms. The LM may include components such as multi-head self-attention, which enables the model to focus on different parts of the input simultaneously, and scaled dot-product attention, which facilitates the weighting of token relationships during processing. Causal masking may be implemented to prevent the model from attending to future tokens in sequence prediction tasks. Layer normalization and residual connections may be incorporated to stabilize training and improve gradient flow through the network. The architecture may also include feed-forward networks for non-linear transformations. During training, the model may learn to predict the next token in a sequence through self-supervised next-token prediction, using cross-entropy loss as an objective function.

Fine-tuning may be performed via reinforcement learning from human feedback, enabling the LM to adapt to specific tasks or improve its output based on user preferences. Some of these tasks—e.g., feedback, prompt generation, etc.—have been outlined above. During inference, the LM may process input text by tokenizing it into discrete tokens, which can represent words, subwords, or other meaningful units of text.

At box 945, it can be judged whether a further iteration 919 is to be executed. The judgment at box 945 can be made based on one more decision criteria, e.g.: positive versus negative validation result of box 935; a number of iterations 919 previously executed; to give just a few examples.

If a further iteration 919 is to be executed, box 920 is re-executed. At this instance of box 920, a new prompt can be generated. This new prompt, in the subsequent iteration 919, can be generated based on the feedback obtained at box 940 of the previous iteration 919.

Optionally, the previous prompt of the previous iteration 919 can be taken into account when generating the new prompt and the subsequent iteration 919.

For instance, the generation of the new prompt can be based on the prompt of the previous iteration 919. For instance, the prompt of the previous iteration can be broken down into certain sections or parts and the impact of each part on the resulting control instructions can be measured. For instance, this can be achieved by modifying the parts of the prompt and testing an impact on the resulting control instructions. Then, based on feedback obtained for the control instructions, those parts of the prompt can be identified that have a positive impact on the control instructions and those parts can be identified that have a negative impact on the control instructions. Those parts of the prompt that have a negative impact may be removed from the prompt and, optionally, be replaced by other parts of, e.g., obtained from a prompt library. Positive parts of the prompt, i.e., those parts that tend to provide a favorable result, may be retained. Scoring of certain parts of the control instructions as positive or negative may be achieved by another language model or heuristics.

It would also be possible that this earlier prompt is provided as additional input to the LM in the subsequent iteration of box 930. In such example, alternatively or additionally to pre-modifying the prompt to the language model, the language model itself may be provided with additional context in the form of the earlier prompt and may be allowed to draw our own conclusions on how to modify its output in view of the positive or negative example posed by that earlier prompt.

If, on the other hand, at box 945 it is judged that a further iteration 919 is not required, the method may commence at box 950. At box 950, the inspection can be executed. The inspection can include the lithography-process inspection tool carrying out one or more tasks as specified in the initial user query obtained at box 905, e.g., an imaging task and/or a defect-detection task and/or a micro-manipulation task and/or a repair task.

A specific example of user input and generated prompt based on the method of FIG. 1 is described next. A user query may be, for example, “Actinic EUV mask imaging for line-edge roughness analysis.” This user query may be included as a task instruction in the prompt. The prompt may have multiple sections, such as the task instruction (from user query), role (e.g., expert for actinic microscopes), context (e.g., via RAG), and output format (e.g., by reference to an API of an actinic microscope). These prompt parts other than the task instruction may be predefined. For RAG context, retrieval access may be provided to a curated knowledge base containing items such as the manual of an actinic microscope, positive and negative control instruction samples, and other relevant information.

Then, the inference—based on this prompt—may output control instructions that are suitable to image a photomask under true exposure conditions. Such control instructions may instruct the actinic microscope to use imaging parameters tailored to the task at hand. Typically, wavelength, resolution, and numerical aperture are fixed for an actinic microscope. On the other hand, certain further imaging parameters may be adjustable. For instance, a typical wavelength may be 13.5 nanometers. A typical numerical aperture may be 0.33. For instance, the control instructions may define one or more properties of time-delayed imaging. Time-delayed imaging may include a synchronized charge shifting on a detector during constant-velocity stage scanning, where encoder-locked line clocks are used to capture images at timed intervals. In this approach, line-shift frequency matching ensures that the relative movement of the sample stage is synchronized with the image acquisition process. The technique may also take into account optical magnification and pixel pitch to determine the appropriate imaging parameters. For instance, stage speed may be set. Other imaging properties that may be set include triggering focus routines, e.g., an auto-leveling process applied to the mask, followed by the acquisition of a through-focus aerial image stack over a z-range at a certain step size, both set by the control instructions. The control instructions may also control one or several auxiliary components of the actinic microscope, to e.g., set and maintain certain environmental and operational parameters; this may include maintaining a vacuum level, stabilizing the mask temperature, and setting the exposure dose equivalent to that of a scanner to avoid detector saturation. The control instructions may also trigger image analysis to solve a defect-detection task which may include detecting and characterizing phase/absorber defects, line-edge roughness, and critical-dimension errors to predict their printability on wafers. To do so, the control instructions may instruct to extract edge contours from the actinic image (e.g., via sub-pixel edge detection), and the local edge position may be measured relative to the best-fit line or center across the feature length. The standard deviation of this detrended edge displacement may give the (root mean square) line-edge roughness, while its power spectral density may reveal the spatial frequency components contributing to line-edge roughness.

At box 955, it is optionally possible to store at least parts of the information created during the execution of the previous boxes. For instance, it would be possible to store the user query of box 905 along with the final control instructions generated in the last iteration 919 of box 925. Such information may serve as ground truth for a subsequent fine-tuning of the LM used for generating the control instructions at box 925. While box 955 is illustrated at the end of the flowchart of FIG. 1, information may also be stored earlier. For instance, upon executing box 905, the user query may be stored, to give just one example.

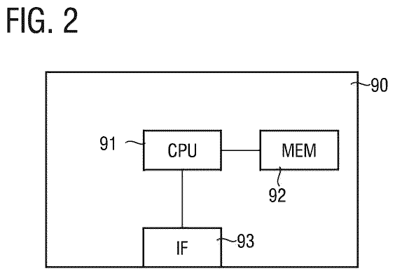

FIG. 2 schematically illustrates an electronic data processing device 90, according to various examples of the present invention. The electronic data processing device 90 includes a processor 91 and a memory 92. The memory 92 may include one or more volatile memory modules and/or one or more non-volatile memory modules. In addition, the electronic data processing device 90 also includes a communication interface 93 through which the processor 91 may receive data and/or transmit data. The processor 91 can load and execute program code from the memory 92. When the processor 91 executes such program code, this causes the processor to perform techniques as disclosed herein, for example: controlling a lithography-process inspection tool, e.g., based on respective control instructions; obtaining context data for the lithography-process inspection tool and/or a sample under investigation in the lithography-process inspection tool; triggering inference, e.g., locally inferencing, one or more machine-learning models such as language models, vision transformer models, etc.; obtaining inputs from a user; providing outputs to the user; etc. For instance, the processor 91 may execute the method of FIG. 1.

In some implementations, each processor 91 (also referred to as a data processor) can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

In some implementations, the one or more machine-learning models can be stored in the memory 92 or one or more storage devices not shown in the figure. Examples of the storage devices include hard disk drives, solid state drives, optical discs (e.g., CD-ROM, DVD, Blu-ray discs). In some implementations, the memory 92 or the one or more storage devices can store tool context data (used at box 910) and sample context data (used at box 915). In this description, any data, model, or other information that can be stored in the memory 92 or the one or more storage devices can also be accessed through the communication interface 93 from one or more remote systems, such as cloud storage server computers.

Summarizing, techniques of preparing control instructions for a lithography-process inspection tool, such as an actinic microscope, a scanning electron microscope (SEM) or an atomic force microscope (AFM), using language models (LMs) have been disclosed. The disclosure provides a method for generating control instructions for the lithography-process inspection tool based on user queries. The method includes obtaining context data for the inspection tool and/or a sample under investigation in the inspection tool, triggering inference of one or more machine-learning models, such as LMs, to generate control instruction proposals, and validating and refining the proposals using additional models and/or human experts.

In general, it may be advantageous to have at least two LMs-one for receiving and processing user queries into prompts, and another for generating the actual control instructions. Optionally, a third LM can be used to validate the output of the second LM. This approach improves security by reducing the risk of malicious user inputs causing unintended actions. For instance, in a scenario with only one LM, a user could potentially request a control instruction that would cause the lithography-process inspection tool to destroy a mask with maximum light intensity. Without proper technical safeguards, this could lead to system corruption and destruction. However, if the first LM is responsible for validating the user query and only triggers the second LM to generate the control instructions when necessary, the risk of such malicious actions is significantly reduced. This idea can be further extended by adding more LMs or splitting tasks between them. By doing so, the security and accuracy of the system can be improved even further.

The disclosure achieves several effects, including improving the accuracy and effectiveness of the control instructions generated for the inspection tool. By using LMs to generate control instruction proposals, the method can leverage the knowledge and expertise encoded in the LM to create high-quality proposals that take into account various factors relevant to the inspection task. The use of multiple models or human experts to validate and refine the proposals further ensures that the final control instructions are reliable and effective.

Although the invention has been shown and described with respect to certain preferred embodiments, equivalents and modifications will occur to others skilled in the art upon the reading and understanding of the specification. The present invention includes all such equivalents and modifications and is limited only by the scope of the appended claims.

For illustration, above, techniques have been disclosed that enable generating control instructions for a lithography-process inspection tool using a LM. A particular strength of the techniques lies in their ability to generate control instructions for a wide variety of tasks specified by user queries. The techniques can handle new tasks, unseen tasks, and tasks across a wide spectrum. This is enabled by a combination of the LM and knowledge-retrieval and prompt-engineering. Thus, while above certain specific examples have been disclosed, the strength of the disclosed techniques lies, in particular, in the ability of the disclosed techniques to handle further examples, tasks etc. for various tools. The disclosure is not limited to the specific explained examples.

As a general rule, it would be possible to use a single LM. In practice, dividing and conquering is often helpful, i.e., breaking down the task of generating a control instruction into smaller sub-tasks, which are then solved sequentially by individual LM “specialists”. This approach can lead to more accurate and effective results. For instance: One LM for control instruction creation (e.g., “Create a control instruction for this task”); One LM for control instruction validation (e.g., “Review this control instruction and identify potential inadequacies”); One LM for explaining why a particular control instruction was recommended (e.g., “Examine this control instruction and explain why it fulfills the task requirements”); One LM for highlighting historical data on which the proposed control instruction is based, i.e., for reasoning (e.g., “Examine this control instruction and explain, using the three most similar historical cases, why this control instruction is effective”). Here, “one LM” can mean that it is actually a different model from the previous ones (i.e., different architecture and/or weights), or it can mean that it is the same LM but prompted differently (e.g., a “creation-specific prompt” versus a “validation-specific prompt”).

For further illustration, in addition or alternatively to using multiple LMs, an approach is to consider dynamic workflows where the sequence of LMs is not fixed but instead depends on intermediate results. This allows for more flexibility and adaptability in the workflow. Intermediate steps can also be performed by other workflows or even human experts, such as a validation experiment (i.e., testing the proposed control instruction). A meta-LM (a high-level LM that oversees the entire process) may be used to schedule subsequent steps based on intermediate results, effectively acting as an “agent” that coordinates the workflow. A specific implementation of this approach could involve: (1) A meta-LM is tasked with creating a control instruction for a focus setting. (2) The meta-LM triggers an LM to generate multiple control instruction proposals for the focus setting at a specific scanning position. (3) For each proposal, a physical simulation is performed using that setting. The simulation engine may employ numerical methods. The simulation engine may employ discretization techniques to approximate continuous systems by breaking them down into discrete elements. Meshing may be used to generate a numerical grid or mesh that represents the geometry of the system under analysis. Time integration may be applied to advance the solution over time, capturing the temporal evolution of the system's behavior. Coupling may enable the interaction between different physical domains or components within the simulation, such as thermal, mechanical, or electromagnetic effects associated with various components of the imaging apparatus. (4) The focus is determined from each simulation result. (5) The results are fed back to the meta-LM, which then decides whether to execute additional agents or proceed to the next step.

As will be appreciated, the meta-LM thus takes the role of an orchestrator that facilitates the coordination and management of tasks, agents, and tools within the workflow for generating control instructions for a lithography-process inspection tool. The orchestrator may be responsible for planning the sequence of operations, decomposing complex tasks into smaller sub-tasks, routing these sub-tasks to appropriate agents or tools, and ensuring agent coordination throughout the process. It may also handle tool selection, context management, state tracking, scheduling, conflict resolution, and evaluation of intermediate results. In practice, the orchestrator may act as a meta-controller that oversees the entire workflow, dynamically adjusting the sequence of operations based on the outcomes of individual tasks or the input from various agents. For example, in the context of generating control instructions for focus settings, the orchestrator may first decompose the task into sub-tasks such as proposal generation, simulation, analysis, and validation. It may then route these sub-tasks to specialized language models, simulation engines, or human experts, as appropriate. The orchestrator may also manage the context of each sub-task, ensuring that relevant data, such as sample characteristics or tool configurations, are appropriately considered. State tracking by the orchestrator may involve monitoring the progress and status of each sub-task in real-time, allowing it to adapt the workflow dynamically. Scheduling decisions made by the orchestrator may ensure that tasks are executed in an optimal order, minimizing conflicts and maximizing efficiency. Conflict resolution by the orchestrator may involve identifying and addressing inconsistencies or errors in intermediate results, such as invalid control instruction proposals or simulation anomalies. Evaluation of these results may be used to determine whether additional processing is required or if the workflow can proceed to the next step.

What is claimed is:

1. A method of generating control instructions for operating a lithography-process inspection tool, the method comprising:
obtaining a user query in free-text format, the user query being indicative of a task to be carried out by the lithography-process inspection tool on a sample,
obtaining tool context data comprising prior knowledge on operation of the lithography-process inspection tool, and
based on the user query and based on the tool context data, triggering one or more inference-runs of at least one language model, to thereby generate the control instructions.

2. The method of claim 1,
wherein the tool context data comprises an operating manual of the lithography-process inspection tool.

3. The method of claim 1,
wherein the tool context data comprises multiple reference control instructions for at least one of the task or one or more other tasks.

4. The method of claim 3,
wherein the tool context data comprises labels associated with each of the multiple reference control instructions, the labels being indicative of whether the respective task is accomplished by the respective reference control instructions.

5. The method of claim 1,
wherein the tool context data comprises at least one of:
an operational status of the lithography-process inspection tool,
an operational history of the lithography-process inspection tool,
a fault indicator of the lithography-process inspection tool,
tool meta data of the lithography-process inspection tool, and/or
sensor data associated with the lithography-process inspection tool.

6. The method of claim 1, wherein the method further comprises:
obtaining sample context data associated with the sample,
wherein the one or more inference-runs of the at least one language model are triggered further based on the sample context data.

7. The method of claim 6,
wherein the sample context data is based on imaging data of the sample and/or based on reference imaging data of a reference sample.

8. The method of claim 6,
wherein the sample context data comprises a free-text-description of one or more properties of the sample.

9. The method of claim 6,
wherein the sample context data comprises a process history of a fabrication process for obtaining the sample.

10. The method of claim 6,
wherein the sample context data comprises an ageing status of the sample.

11. The method of claim 1,
wherein the sample is a semiconductor wafer or a lithography mask.

12. The method of claim 1,
wherein the control instructions comprise script code for controlling one or more modules of the lithography-process inspection tool or for analyzing imaging data acquired using the lithography-process inspection tool.

13. The method of claim 1, wherein said generating of the control instructions comprises one or more iterations, each iteration comprising:
generating a respective prompt for the at least one language model based on the user query, and
triggering the inference-run of the at least one language model based on the respective prompt.

14. The method of claim 13, wherein each iteration comprises:
validating an output of the given one of the at least one language model.

15. The method of claim 14, wherein each iteration comprises:
based on said validating, selectively triggering a subsequent iteration.

16. The method of claim 14,
wherein said validating is based on a respective one of the at least one language model.

17. The method of claim 14,
wherein said validating is based on a digital twin of the lithography-process inspection tool.

18. The method of claim 13,
wherein the respective prompt in a given iteration of the one or more iterations is generated further based on a compressed representation of at least a part of the tool context data and optionally sample context data associated with the sample.

19. The method of claim 13,
wherein the respective prompt in a given iteration of the one or more iterations requests the at least one language model to access the tool context data and optionally sample context data associated with the sample.

20. The method of claim 13,
wherein said generating of the control instructions comprises multiple iterations,
wherein the respective prompt in a given iteration of the multiple iterations is generated based on feedback on an output of the language model in a preceding iteration and optionally based on the respective prompt of the preceding iteration.

21. The method of claim 20,
wherein the feedback comprises a user feedback and/or is generated by a respective one of the at least one language model.

22. The method of claim 1,
wherein the control instructions specify one or more of the following elements:
an imaging parameter value of the lithography-process inspection tool imaging the sample,
an image analysis algorithm for analyzing imaging data acquired using the lithography-inspection tool,
one or more branching positions for branching between different control branches depending on one or more ad-hoc decision criteria, and/or
one or more event-triggered control items.

23. The method of claim 1,
wherein the user query specifies one or more of the following elements:
an imaging parameter value of the lithography-process inspection tool imaging the sample,
an image analysis algorithm for analyzing imaging data acquired using the lithography-inspection tool,
a defect type of a defect detection task,
a type of the sample,
a time constraint for the task,
a restriction for deviating from one or more reference control instructions; and/or
a repair strategy of a repair task.

24. The method of claim 1, further comprising:
obtaining, from the at least one language model, information on a reasoning associated with the control instructions.

25. The method of claim 24,
wherein the information on the reasoning associated with the control instructions comprises pointers to at least sections of one or more reference control instructions.

26. The method of claim 1, further comprising:
fine-tuning of the at least one language model based on reference user queries and reference control instructions.

27. The method of claim 1,
wherein the task is at least one of an imaging task, a defect-detection task, a micro-manipulation task, or a repair task.

28. An electronic data processing device, comprising a processor and a memory, the processor being configured to load program code from the memory and execute the program code, the processor, upon loading and executing the program code, performing the method of claim 1.
